(19) United States
(12) Patent Application Publication
(10) Pub. No.: US 2011/0156765 A1
(43) Pub. Date: Jun. 30, 2011

(54) DATA OUTPUT CIRCUIT PROVIDED WITH OUTPUT DRIVER

(75) Inventor: Keun Kook Kim, Gyeonggi-do (KR)

(73) Assignee: HYNIX SEMICONDUCTOR INC., Gyeonggi-do (KR)

(21) Appl. No.: 12/833,077

(22) Filed: Jul. 9, 2010

(30) Foreign Application Priority Data
Dec. 24, 2009 (KR) 10-2009-0130796

(51) Int. Cl. H03K 3/00

(52) U.S. Cl. 327/109

(57) ABSTRACT

Provided is a data output circuit having an output driver that outputs accurate data voltages while preventing unwanted current leakage through switching CMOS transistors. The data output circuit includes a pre-driver, an output driver and a high resistance resistor. The pre-driver is configured to pre-drive a data pulse. The output driver is configured to receive the output signal of the pre-driver. The high resistance resistor is configured to adjust the output signal of the pre-drive so that a slope of the output signal is gradual r and to provide the smoothed output signal to the output driver. The high resistance resistor is a gate resistor of a MOS transistor of the output driver.

### CROSS-REFERENCES TO RELATED APPLICATION

The present application claims priority under 35 U.S.C. §119(a) to Korean application number 10-2009-0130796, filed on Dec. 24, 2009, in the Korean Intellectual Property Office, which is incorporated herein by reference in its entirety as set forth in full.

### BACKGROUND

1. Technical Field

The present invention relates to a data output circuit, and more particularly, to a data output circuit provided with an output driver.

2. Related Art

In general, a semiconductor memory apparatus may be divided into a core area configured to process data and a data input/output area configured to transmit and receive signals to and from an external different circuit apparatus. The data input/output area may include a data input circuit and a data output circuit. The data input circuit is configured to buffer data inputted from outside and then to provide the buffered data to the core area. The data output circuit is configured to receive a data signal transferred from the core area and pull-up and pull-down drive data such that the data can be accurately transferred to an external different semiconductor apparatus.

Parameters determining the characteristics of the data output circuit include slew rates. The slew rates indicate how fast a voltage level of data outputted from the data output circuit changes, and represent a voltage gradient with respect to time. Such a slew rate may be affected by a semiconductor fabrication process or operation temperature.

Currently, to output an accurate data voltage in the data output circuit, efforts to reduce slew rate of data are being continuously made. As a part of the efforts, there is provided a method which smoothes the slope of a data pulse inputted to an output driver composing the data output circuit.

To smooth the slope of the data pulse inputted to the output driver, a conventional method has been proposed in which a high resistor is connected between a pre-driver and the output driver.

However, when a resistor, having a relatively large resistance, is disposed at an output terminal of the pre-driver, then that resistance is likely to suffer the disadvantage in that the area of the data output circuit increases.

In another conventional method, turn on/off times of an NMOS transistor and a PMOS transistor in an output driver configured in a Complementary Metal-Oxide-Semiconductor (CMOS) type are sequentially delayed to control the slew rate of a data pulse.

In the above-described method, however, since the turn on/off times of the NMOS transistor and the PMOS transistor are sequentially delayed as illustrated in FIG. 1, an extended time interval in which the NMOS transistor and the PMOS transistor are simultaneously turned on may occur, thereby increasing current consumption. The extended time interval is indicated by the symbol X in FIG. 1.

### SUMMARY

In one embodiment of the present invention, a data output circuit includes: a pre-driver configured to pre-drive a data pulse, an output driver configured to receive an output signal of the pre-driver, and a high resistance resistor configured to adjust the output signal of the pre-driver so that a slope of the output signal is gradual and to provide the smoothed output signal to the output driver, wherein the high resistance resistor is a gate resistor of a MOS transistor of the output driver.

In another embodiment of the present invention, a data output circuit includes: a pull-up circuit block configured to drive a first signal; a pull-down circuit block configured to drive a second signal being opposite to the first signal; a first resistor unit configured to adjust the first signal so as to have a gradual slope and to provide to the first signal having the gradual slope to the pull-up circuit block; and a second resistor unit configured to adjust the second signal so as to have a gradual slope and to provide the second signal having the gradual slope to the pull-down circuit block, wherein the first resistor unit comprises gate resistors of a MOS transistor of the pull-up circuit block, and the second resistor unit comprises gate resistors of a MOS transistor of the pull-down circuit block.

In another embodiment of the present invention, a data output circuit includes: a pre-driver configured to generate an up signal in response to up data of a data pulse; a PMOS transistor configured to drive the up signal; a resistor unit configured to adjust the up signal so as to a gradual slope and to provide to the PMOS transistor; and a switching unit configured to provide a power supply voltage to the PMOS transistor in response to the up data of the data pulse.

In another embodiment of the present invention, a data output circuit includes: pre-driver configured to generate a down signal in response to down data of a data pulse; an NMOS transistor configured to drive the down signal; a resistor unit configured to smooth the slope of the down signal to provide to the NMOS transistor; and a switching unit configured to provide a ground voltage to the NMOS transistor in response to the down data of the data pulse.

### BRIEF DESCRIPTION OF THE DRAWINGS

Features, aspects, and embodiments are described in conjunction with the attached drawings, in which:

FIG. 1 is a simulation diagram showing output pulses of a conventional output driver;

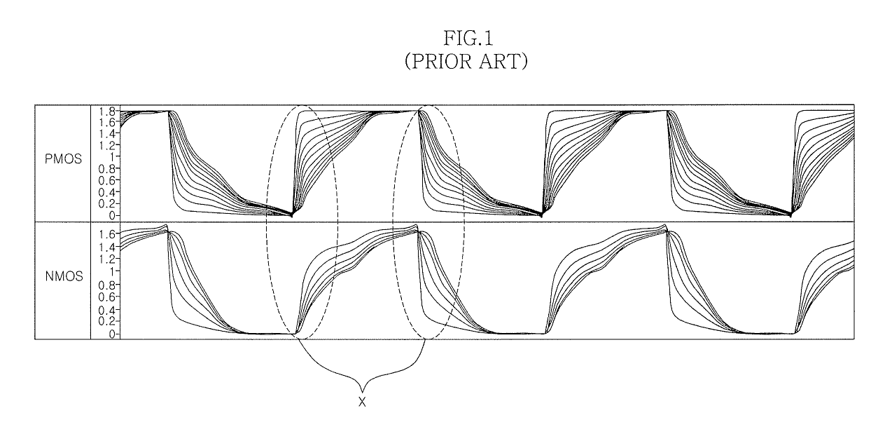

FIG. 2 is a circuit diagram of a data output circuit according to one embodiment;

FIG. 3 schematically illustrates the layout of a pull-up circuit block of FIG. 2;

FIG. 4 schematically illustrates the layout of a pull-down circuit block of FIG. 2;

FIG. 5 is a circuit diagram of a data output circuit according to another embodiment;

FIG. 6 schematically illustrates the layout of a pull-up circuit block of FIG. 5;

FIG. 7 schematically illustrates the layout of a pull-down circuit block of FIG. 5;

FIG. 8 is a diagram showing results obtained by simulating output pulses of the data output circuit according to the embodiment; and

FIG. 9 is a circuit diagram of a data output circuit according to another embodiment.

### DETAILED DESCRIPTION

Hereinafter, a data output circuit provided with an output driver according to the present invention will be described below with reference to the accompanying drawings through preferred embodiments.

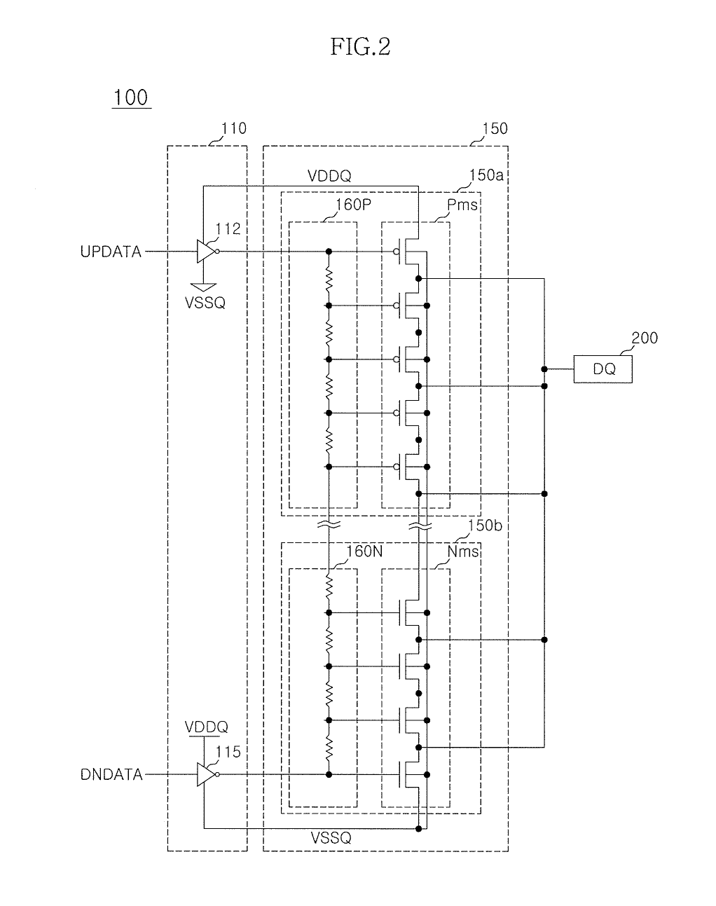

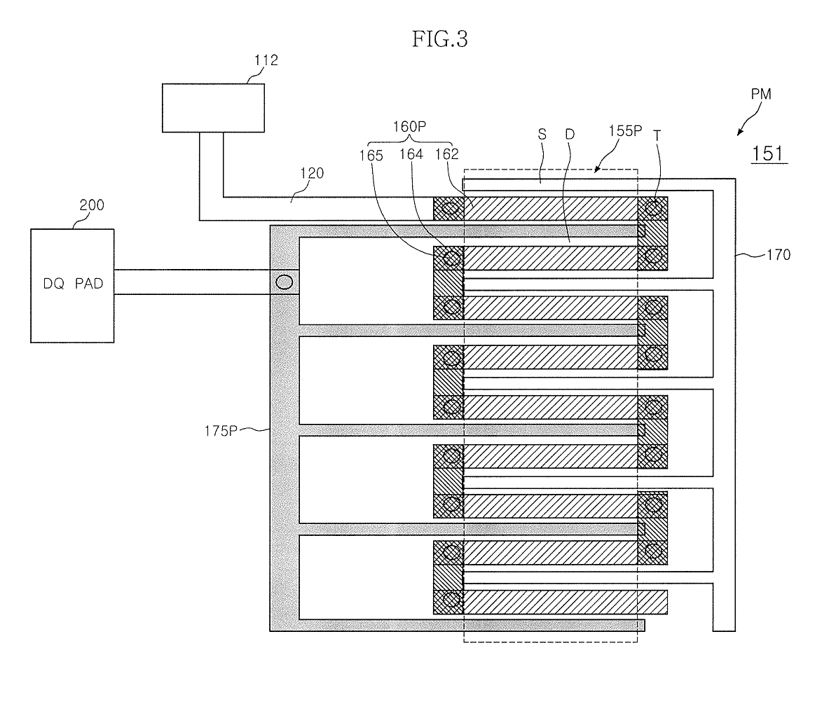

FIG. 2 illustrates a data output circuit according to one embodiment. FIG. 3 illustrates the layout of a pull-up circuit block of FIG. 2.

Referring to FIG. 2, the data output circuit 100 includes a pre-driver 110 and an output driver 150.

The pre-driver 110 may include a first pre-driver 112 configured to drive an up data signal (UPDATA) and a second pre-driver 115 configured to drive a down data signal (DNDATA). Each of the first and second pre-drivers 112 and 115 may be configured with a CMOS inverter including an NMOS transistor and a PMOS transistor.

The output driver 150 may include a pull-up circuit block 150a and a pull-down circuit block 150b. The pull-up circuit block 150a is configured to pull-up amplify an UPDATA signal outputted from the first pre-driver 112, that is, the pre-driven UPDATA signal, and then provide the amplified data to a data (DQ) pad 200. The pull-down circuit block 150b is configured to pull-down amplify DNDATA signal outputted from the second pre-driver 115, that is, the pre-driven DNDATA, and then provide the amplified data to the data pad 200.

The pull-up circuit block 150a may include a first resistor unit 160P and a large-sized PMOS transistor Pms. The first resistor unit 160P may include a plurality of high resistors connected in series, for example. The large-sized PMOS transistor Pms is configured to switch a power supply voltage VDDQ to the data pad 200 in response to the output signal from the first pre-driver 112. The large-sized PMOS transistor Pms may have a larger size than MOS transistors composing the first and second pre-drivers 112 and 115, as indicated by the name of the large-sized PMOS transistor Pms. One variation is that the large-sized PMOS transistor may be configured by connecting a plurality of small-sized PMOS transistors in parallel, in consideration of design convenience and area efficiency. Hereinafter it is understood that Pms will not only denote the large-sized PMOS transistor, but also denote a plurality of PMOS transistors connected in parallel to compose the large-sized PMOS transistor.

The pull-down circuit block 150b may include a second resistor unit 160N and a large-sized NMOS transistor Nms. The second resistor unit 160N may include a single resistor having a relatively large resistance or include a plurality of resistors connected in series, similar to the above noted variation of the first resistor unit 160P. The large-sized NMOS transistor Nms is configured to discharge a voltage provided to the data pad 200 to a ground terminal VSSQ in response to the output signal of the second pre-driver 115. The large-sized NMOS transistor Nms may also be configured to have a larger size than that of the MOS transistors composing the first and second pre-drivers 112 and 115, and may be configured by connecting a plurality of small-sized NMOS transistors in parallel. Hereinafter, it is understood that Nms will not only denote the large-sized NMOS transistor, but also be understood to denote a plurality of NMOS transistors connected in parallel to compose the large-sized NMOS transistor.

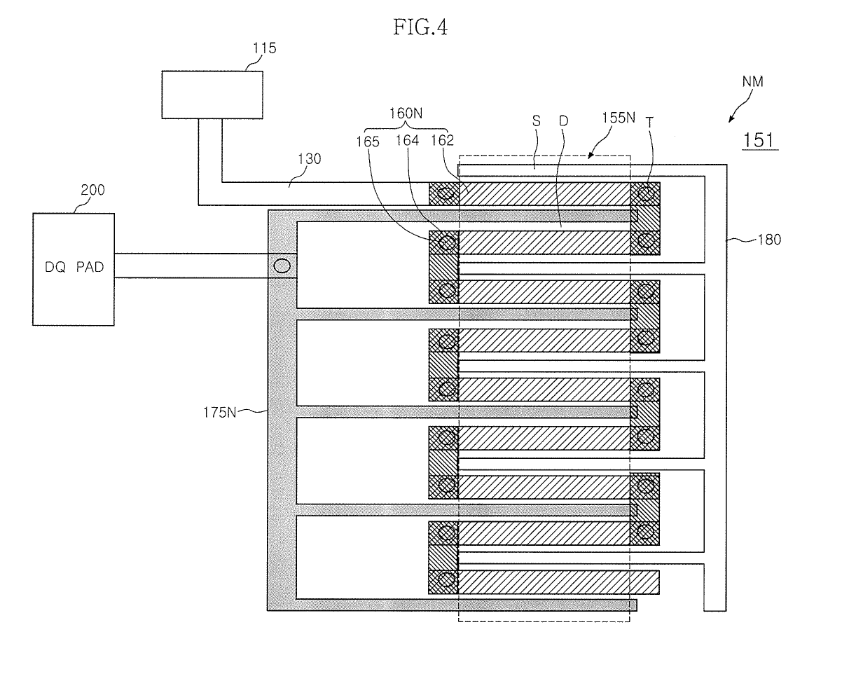

In this embodiment, it has been illustrated in the circuit diagram of FIG. 2 that the first and second resistor units 160P and 160N are connected to the respective gates of the large-sized PMOS transistor Pms and the large-sized NMOS transistor Nms. However, as illustrated in FIGS. 3 and 4, the first and second resistor units 160P and 160N can be gate resistors of the large-sized PMOS transistor and the large-sized NMOS transistor.

Referring to FIG. 3, the large-sized PMOS transistor Pms includes an active area 155P formed in a semiconductor substrate 151 and a gate 160P formed on the active area 155P to extend in a sinuous zigzag shape without being cut. At this time, the active area 155P may include p-type impurities. The active area 155P at one side of a first gate electrode 162 becomes a source area S, and the active area 155P at the other side of the first gate electrode 162 becomes a drain area D.

The gate 160P may include at least one of a bending portion. For example, the gate 160p includes a plurality of first gate electrodes 162 preferably arranged in parallel on the active area 155P, a plurality of second gate electrodes 164 which alternately connect ends of the first gate electrodes 162 such that the first gate electrodes 162 are connected in series using the second gate electrodes 164 to form a sinuous zigzag shape, and a plurality of contacts 165 which electrically connect the first and second gate electrodes 162 and 164.

The gate 160P is electrically contacted with an output signal interconnection 120 of the first pre-driver 112. FIG. 3 illustrates that the output signal interconnection 120 of the first pre-driver 112 is contacted with the first gate electrode 162 positioned at one side end. However, the output signal interconnection 120 may be connected to any one of the first and second gate electrodes 162 and 164. Furthermore, the gate 160P may be configured only with the first gate electrodes 162. In this case, the first pre-driver 112 may require a plurality of output signal interconnections 120 to transfer signals to the first gate electrodes 162, respectively.

The respective source areas S of the PMOS transistors are electrically connected to interconnections through which a power supply voltage VDDQ is provided. Hereinafter, the interconnections are referred to as power supply voltage interconnections 170. The respective drain areas D of the PMOS transistors are connected to interconnections connected to the data pad 200. Hereinafter, the interconnections are referred to pad interconnections 175P. At this time, when the power supply voltage interconnections 170 are positioned at the respective source areas S and the pad interconnections 175 are positioned at the respective drain areas D, signals may be provided and transferred to the source and drain areas S and D at the substantially same time without substantial signal delay.

Meanwhile, as illustrated in FIG. 4, the NMOS transistor Nms may be integrated in a manner similar to the integrated form of the PMOS transistor Pms. That is, the NMOS transistor Nms includes an active area 155N having sources S and drains D formed therein and a gate 160N formed on the active area 155N to extend in a zigzag shape. The active area 155N of the NMOS transistor Nms includes an n-type impurity area. Similar to the gate 160P of the PMOS transistor PM, the gate 160N may include at least one of a bending portion. For example, the gate 160N of the NMOS transistor Nms includes a plurality of first gate electrodes 162 which are arranged in parallel, a plurality of second gate electrodes 164 which alternately connect the ends of the first gate electrodes 162 such that the first gate electrodes 162 are connected in series via the second gate electrodes 164 which form a zigzag shape, and a plurality of contacts 165 which electrically connect together the first and second gate electrodes 162 and 164.

The gate 160N of the NMOS transistor Nms is electrically contacted with an output signal interconnection 130 of the second pre-driver 115. At this time, the output signal interconnection 130 of the second pre-driver 115 may be contacted with any portion of the gate 160N of the NMOS transistor Nms, like that of the PMOS transistor Pms.

Similar to the configuration of the PMOS transistor Pms, the gate 160N of the NMOS transistor Nms may be configured only with the first gate electrodes 162. In this case, the second pre-driver 112 may require a plurality of output signal interconnections 130 to transfer signals to the first gate electrodes 162, respectively.

The respective source areas S of the NMOS transistor Nms are electrically connected to interconnections through which a ground voltage VSSQ is provided. Hereinafter, the interconnections are referred to as ground voltage interconnections 180. The respective drain areas D are connected to interconnections connected to the data pad 200. Hereinafter, the interconnections are referred to as pad interconnections 175N.

Both of the pull-up and pull-down circuit blocks 150a and 150b composing the output driver 150 according to this embodiment are arranged on the active area 155, because the first and second resistor units 160P and 160N for improving a slew rate are configured function as gate resistors of the NMOS and PMOS transistors Nms and Pms. Accordingly, a separate area for arranging the first and second resistor units 160P and 160N is not required.

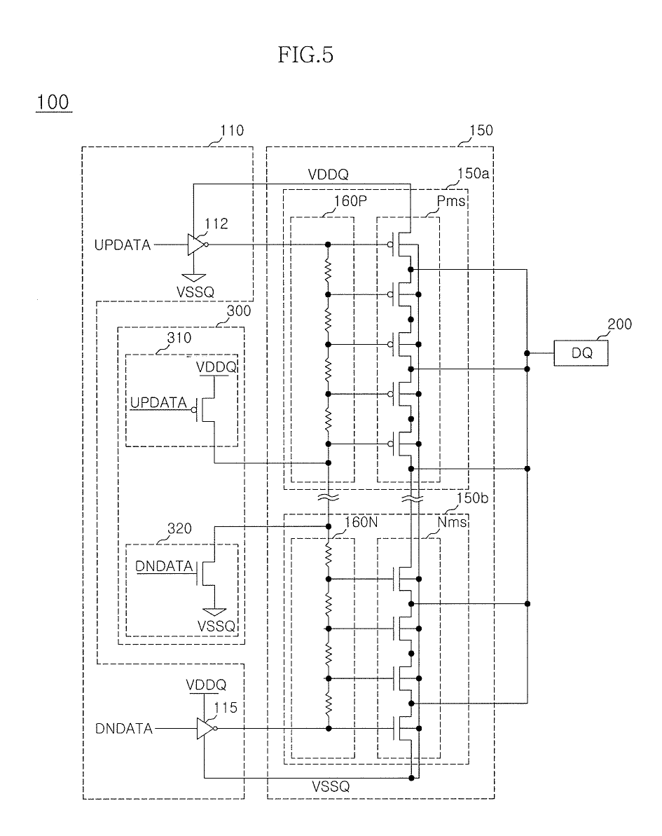

To prevent the PMOS and NMOS transistors Pms and Nms from being simultaneously turned on by the delay of the first and second resistor units 160P and 160N, a control circuit block 300 may be further connected to the pull-up and pull-down circuit blocks 150a and 150b, as illustrated in FIG. 5.

The control circuit block 300 may include a first switching unit 310 connected to the pull-up circuit block 150a and a second switching unit 320 connected to the pull-down circuit block 150b.

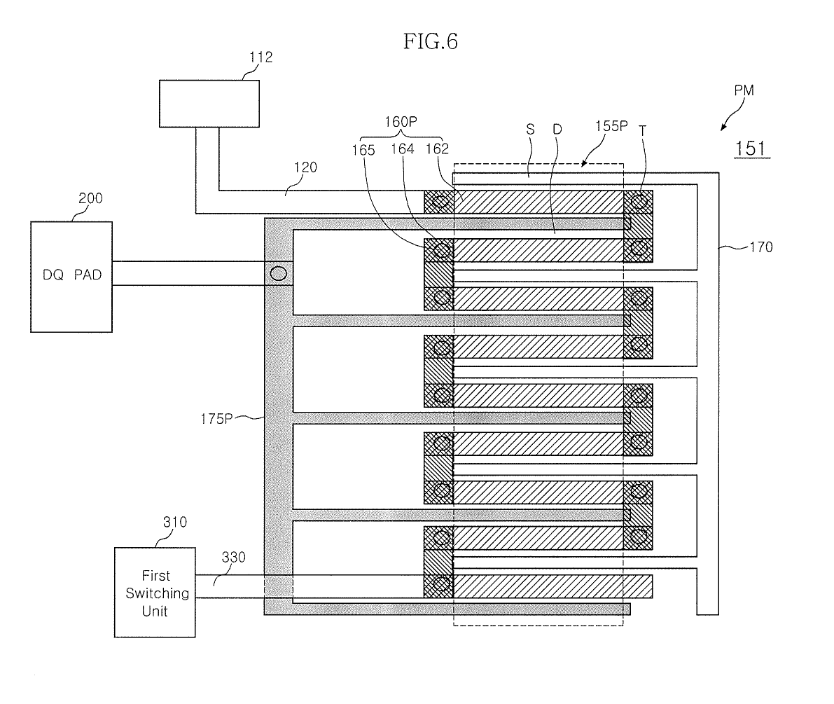

The first switching unit 310 may be configured with a PMOS transistor which switches the power supply voltage VDDQ in response to an up data signal (UPDATA). The first switching unit 310 is connected to the first resistor unit 160P. As illustrated in FIG. 6, an interconnection 330 connecting the first switching unit 310 to the first resistor unit 160P may be formed to be spaced at a predetermined distance away from the output signal interconnection 120 of the first pre-driver 112. In other words, the output signal interconnection 120 of the first pre-driver 112 may be connected to one end of the gate 160P of the PMOS transistor Pms, and the first switching unit 310 may be connected to the other end thereof. Accordingly, the power supply voltage VDDQ is provided to both ends of the gate of the PMOS transistor Pms having a relatively high resistance resistor at the same time, thereby removing signal delay caused by the high resistance resistor.

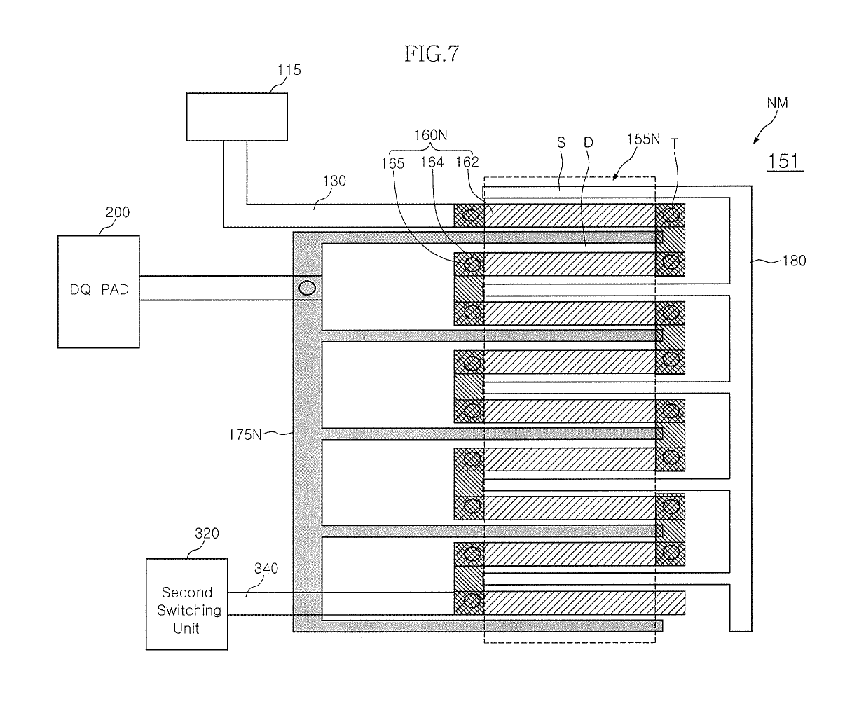

The second switching unit 320 may be configured with an NMOS transistor which discharges a voltage applied to the second resistor unit 160N in response to a down data signal (DNDATA). The voltage is a gate voltage of the NMOS transistor Nms. As illustrated in FIG. 7, the second switching unit 320 is connected to the second resistor unit 160N, and an interconnection 340 connecting the second resistor unit 160N is formed to be spaced at a predetermined distance away from the output signal interconnection 130 of the second pre-driver 115. That is, the second pre-driver 115 may be connected to one end of the gate 160N of the NMOS transistor Nms, and the second switching unit 310 may be connected to the other end thereof. Accordingly, the voltages applied through both ends of the gate of the NMOS transistor Nms having a relatively high resistance resistor can be discharged at the same time.

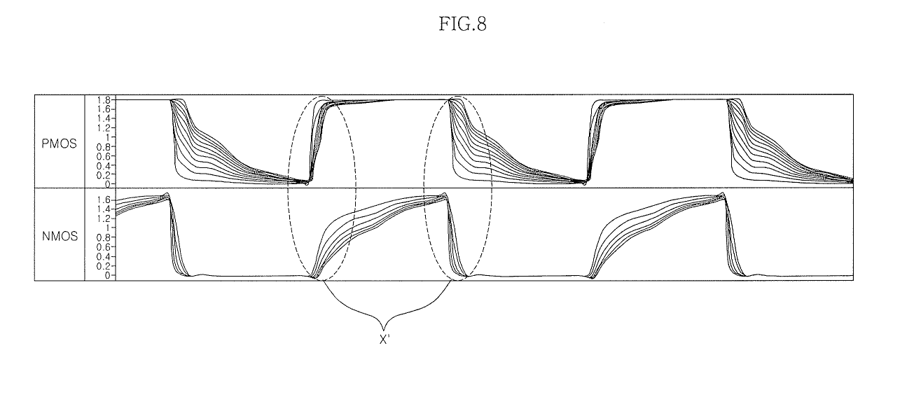

FIG. 8 shows results obtained by simulating the output driver 100 configured in such a manner. As shown in FIG. 8, the output pulses of the pull-up and pull-down circuit blocks 150a and 150b using the first and second resistor units 160P and 160N and the control circuit block 300 do not exhibit defects such as overshoot or undershoot, and are generated without substantial delay. Therefore, a simultaneous turn-on interval X′ does not occur at a rising edge and a falling edge. That is, since the slope of the falling edge has a gentle value and the slope of the rising edge has a gentle value, the pull-up and pull-down circuit blocks 150a and 150b are not turned on at the same time. Accordingly, it is possible to prevent or at least minimize current leakage.

In the above-described embodiments, the gates of the PMOS and NMOS transistors Pms and Nms composing the pull-up and pull-down circuit blocks 150a and 150b are used as resistors for reducing the slew rate of data pulses. As will be described in the following embodiment, however, the interconnections 120 and 130 connecting the pre-driver 112 or 115 to the PMOS transistor Pms and the NMOS transistor Nms may be configured to be used as resistors.

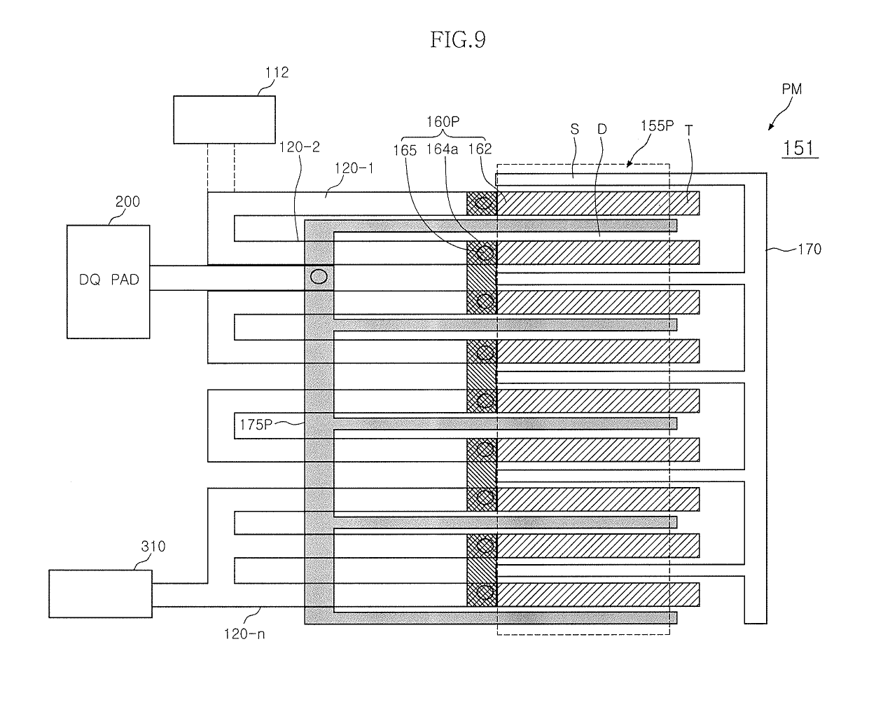

That is, referring to FIG. 9, the gate 160P of the PMOS transistor Pms may be configured only with the first gate electrodes 162 arranged in parallel on the active area 155, and output signal interconnections 120-1 through 120n of the first pre-driver 112, of which the number corresponds to the number of the first gate electrodes 162, may be provided and connected to the first gate electrodes 162, respectively. At this time, one ends of the first gate electrodes 162 may be selectively connected by the second gate electrodes 164, in order to electrically connect the first pre-driver 112 to the first gate electrodes 162. Furthermore, one ends of the output signal interconnections 120-1 through 120-n may be all bound.

Then, the output signal interconnections 120-1 through 120-n may be used as resistors to smooth the slope of the data output pulses.

At this time, a constant area is allocated to the portion in which the output signal interconnections 120-1 through 120-n are formed, regardless of whether the output signal interconnections 120-1 through 120-n are configured with one interconnection or multiple interconnections. Therefore, although the output interconnections of the first pre-driver 112 are configured with multiple interconnections, the area thereof does not increase.

In this embodiment, the pull-up circuit block has been taken as an example. However, the configuration may be applied to the pull-down circuit block.

According to the embodiments of the present invention, the gates of the MOS transistors composing the pull-up and pull-down circuit blocks or the output signal interconnections of the pre-driver are used as resistors which results in substantially smoothing the slope of data pulses inputted to the output driver. Accordingly, since a high resistance is generated by the gate electrodes arranged in the predetermined area, that is, the active area. It is therefore possible to significantly reduce a circuit design area.

Furthermore, the control circuit block is further connected to the pull-up and pull-down circuit blocks to provide the pre-driven data pulses to both ends of the gates of the MOS transistors composing the pull-up and pull-down circuit blocks. Therefore, it is possible to reduce signal delay.

Accordingly, the slope of the rising and falling edges of the data pulses may be smoothed, and the overlapping time portions therebetween may be reduced. Therefore, it is possible to prevent or at least minimize the occurrence that the pull-up and pull-down circuit units are turned on at the same time.

While certain embodiments have been described above, it will be understood to those skilled in the art that the embodiments described are by way of example only. Accordingly, the device and method described herein should not be limited based on the described embodiments. Rather, the apparatus described herein should only be limited in light of the claims that follow when taken in conjunction with the above description and accompanying drawings.

What is claimed is:

1. A data output circuit comprising:
a pre-driver configured to pre-drive a data pulse;
an output driver configured to receive an output signal of the pre-driver; and
a high resistance resistor configured to adjust the output signal of the pre-driver so that a slope of the output signal is gradual and to provide the output signal having the gradual slope to the output driver,
wherein the high resistance resistor is a gate resistor of a MOS transistor of the output driver.

2. The data output circuit according to claim 1, wherein the MOS transistor comprises an active area, and a gate having at least one of a bending portion on the active area.

3. The data output circuit according to claim 2, wherein the gate comprises:
a plurality of first gate electrodes substantially in parallel to each other and on the active area;
a plurality of second gate electrodes adjacent to the active area and substantially perpendicular to the first gate electrodes such that each second gate electrode is connected to ends of adjacent first gate electrodes so that the first gate electrodes connected to the second gate electrodes form a substantial sinuous zigzag shape of the gate of the MOS transistor; and
a plurality of contacts electrically connecting the first and second gate electrodes together.

4. The data output circuit according to claim 3, further comprising an output signal interconnection electrically connecting the pre-driver to the gate.

5. The data output circuit according to claim 4, further comprising a control circuit block coupled to the data pulse, the control circuit block configured to transfer a power supply voltage or an output voltage to the gate in response to the data pulse.

6. The data output circuit according to claim 5, wherein the output signal interconnection is disposed at a predetermined distance away from an interconnection connecting the control circuit and the gate.

7. A data output circuit comprising:
a pull-up circuit block configured to drive a first signal;
a pull-down circuit block configured to drive a second signal being opposite to the first signal;
a first resistor unit configured to adjust the first signal so as to have a gradual slope and to provide to the first signal having the gradual slope to the pull-up circuit block; and
a second resistor unit configured to adjust the second signal so as to have a gradual slope and to provide the second signal having the gradual slope to the pull-down circuit block,
wherein the first resistor unit comprises gate resistors of a MOS transistor of the pull-up circuit block, and the second resistor unit comprises gate resistors of a MOS transistor of the pull-down circuit block.

8. The data output circuit according to claim 7, further comprising a first pre-driver configured to transfer the first, wherein the first pre-driver is driven in response to receiving the first signal.

9. The data output circuit according to claim 7, further comprising a second pre-driver configured to transfer the second signal, wherein the second pre-driver is driven in response to inputting the second signal.

10. The data output circuit according to claim 7, wherein the MOS transistor of the pull-up circuit block is a PMOS transistor.

11. The data output circuit according to claim 10, wherein the PMOS transistor comprises an active area containing p-type impurities, and a gate having a substantial zigzag shape on the active area.

12. The data output circuit according to claim 11, wherein the gate of the PMOS transistor comprises:
a plurality of first gate electrodes arranged substantially in parallel to each other on the active area;
a plurality of second gate electrodes arranged substantially perpendicular to the first gate electrodes such that each second gate electrode connects ends of adjacent first gate electrodes so that the first gate electrodes and the second gate electrodes form the substantial sinuous zigzag shape of the gate of the PMOS transistor; and
a plurality of contacts electrically connecting together the first gate electrodes to the second gate electrodes.

13. The data output circuit according to claim 12, further comprising a first switching unit configured to provide a power supply voltage to the gate of the PMOS transistor in response to the first signal.

14. The data output circuit according to claim 13, wherein the active area at one side of the gate of the PMOS transistor is a source area and the active area at another side of the gate of the PMOS transistor is a drain area,
wherein the up signal is input to the source area of the PMOS transistor and the output signal of the first switching unit is input to the drain area of the PMOS transistor.

15. The data output circuit according to claim 7, wherein the MOS transistor of the pull-down circuit block is an NMOS transistor.

16. The data output circuit according to claim 15, wherein the NMOS transistor comprises an active area containing n-type impurities, and
a gate comprising a substantial sinuous zigzag shape that extends on the active area.

17. The data output circuit according to claim 16, wherein the gate of the NMOS transistor comprises:
a plurality of first gate electrodes arranged substantially in parallel to each other on the active area;
a plurality of second gate electrodes arranged substantially perpendicular to the first gate electrodes in which each second gate electrode connects ends of adjacent first gate electrodes so that the first gate electrodes connected to the second gate electrodes; and
a plurality of contacts electrically connecting the first and second electrodes together.

18. The data output circuit according to claim 17, wherein the active area in one side of the gate of the NMOS transistor is a source and the active area in another side of the gate of the NMOS transistor is a drain.

19. The data output circuit according to claim 18, wherein the second signal is inputted to the gate of the NMOS transistor.

20. A data output circuit comprising:
a pre-driver configured to receive and to transfer an UPDATA signal;
a PMOS transistor configured to drive the UPDATA signal;
a resistor unit configured to adjust the UPDATA signal so as to have a gradual slope and to provide the UPDATA signal having the gradual slope to the PMOS transistor; and
a switching unit configured to provide a power supply voltage to the PMOS transistor in response to receiving the UPDATA signal.

21. The data output circuit according to claim 20, wherein the PMOS transistor comprises an active area containing p-type impurities, and a gate extending on the active area such that the gate also comprises the resistor unit.

22. The data output circuit according to claim 21, wherein the gate of the PMOS transistor comprises:
a plurality of first gate electrodes arranged substantially in parallel to each other on the active area;
a plurality of second gate electrodes arranged substantially perpendicular to the first gate electrodes such that the second gate electrodes connect ends of adjacent first gate electrodes so that the first gate electrodes connected to the second gate electrodes form a substantial zigzag shape; and
a plurality of contacts electrically connecting together the first gate electrodes to the second gate electrodes.

23. The data output circuit according to claim 20, wherein the gate of the PMOS transistor comprises a plurality of gate electrodes arranged in parallel on the active area.

24. The data output circuit according to claim 23, further comprising a plurality of output signal interconnections connecting together the pre-driver to the gate electrodes of the PMOS transistor, wherein the plurality of signal interconnections comprise the resistor unit.

25. The data output circuit according to claim 20, wherein the pre-driver is configured with a MOS transistor, and the PMOS transistor is larger than the MOS transistor of the pre-driver.

26. A data output circuit comprising:
a pre-driver configured to transfer a DNDATA signal
an NMOS transistor configured to drive the DNDATA signal;
a resistor unit configured to adjust the DNDATA signal so as to have a gradual slope and to provide the DNDATA signal having the gradual slope to the NMOS transistor; and
a switching unit configured to provide a ground voltage to the NMOS transistor in response to the DNDATA signal.

27. The data output circuit according to claim 26, wherein the NMOS transistor comprises an active area containing n-type impurities, and a gate of the NMOS transistor extending onto the active area such that the gate of the NMOS transistor comprises the resistor unit.

28. The data output circuit according to claim 27, wherein the gate of the NMOS transistor comprises:
a plurality of first gate electrodes arranged substantially in parallel on the active area;
a plurality of second gate electrodes arranged substantially perpendicular to the first gate electrodes in which the second gate electrodes connect ends of adjacent first gate electrodes wherein the first gate electrodes connected to the second gate electrodes form the zigzag shaped gate of the NMOS transistor; and
a plurality of contacts electrically connecting together the first gate electrodes to the second gate electrodes.

29. The data output circuit according to claim 26, wherein the gate of the NMOS transistor comprises a plurality of gate electrodes arranged substantially in parallel on the active area.

30. The data output circuit according to claim 29, further comprising a plurality of signal interconnections connecting together the pre-driver to the gate electrodes of the NMOS transistor,
wherein the plurality of signal interconnections comprise the resistor unit.

31. The data output circuit according to claim 26, wherein the pre-driver is comprises a MOS transistor, and the NMOS transistor is larger than the MOS transistor of the pre-driver.
